(19) United States
(12) Patent Application Publication
(10) Pub. No.: US 2025/0234609 A1
(43) Pub. Date: Jul. 17, 2025

(54) POWER SEMICONDUCTOR DEVICE INTEGRATED SELECTABLE GATE RESISTANCE

(71) Applicant: Microchip Technology Incorporated, Chandler, AZ (US)

(72) Inventor: Perry Schugart, West Chester, PA (US)

(73) Assignee: Microchip Technology Incorporated, Chandler, AZ (US)

(21) Appl. No.: 18/830,987

(22) Filed: Sep. 11, 2024

Related U.S. Application Data
(60) Provisional application No. 63/621,837, filed on Jan. 17, 2024.

(51) Int. Cl. H01L 29/06; H01L 23/48; H01L 25/07; H01L 29/16

(52) U.S. Cl. CPC H10D 62/127; H01L 23/481; H01L 25/071; H10D 62/8325

(57) ABSTRACT

A power semiconductor device is provided that includes paralleled transistor cells, and a common source, a common drain and a common gate operatively coupled to the paralleled transistor cells. The power semiconductor device also includes a plurality of common gate contact pads operatively coupled to the common gate, and one or more resistors coupled to respective one or more common gate contact pads of the plurality of common gate contact pads. The one or more resistors are also coupled between the respective one or more common gate contact pads and the common gate. The plurality of common gate contact pads provide a selectable resistive decoupling of the common gate by connection of one of the plurality of common gate contact pads.

### CROSS-REFERENCE TO RELATED APPLICATION(S)

The present application claims priority to U.S. Provisional Patent Application No. 63/621,837, entitled: A Power Semiconductor Device Integrated Selectable Gate Resistance, filed on Jan. 17, 2024, the content of which is hereby incorporated by reference in its entirety.

### TECHNOLOGICAL FIELD

The present disclosure relates generally to semiconductor devices and, in particular, to a power semiconductor device with selectable gate resistance.

### BACKGROUND

Silicon transistors have long been used in electronic devices, driving technological advancements across various industries. As demands for higher efficiency and increased power handling capabilities have intensified, however, limitations of traditional silicon transistors have become increasingly evident, particularly in high-power applications. One of the key challenges faced by silicon transistors is their inherent limitation in switching speed, leading to higher switching losses and reduced efficiency in certain applications.

Recognizing the need for breakthroughs in power electronics, researchers and engineers have turned their attention to alternative materials, and silicon carbide (SiC) has emerged as a frontrunner in this quest for enhanced performance. One of the standout features of SiC transistors, notably power metal-oxide-semiconductor field-effect transistors (MOSFETs), is their ability to switch (turn on and turn off) at significantly faster speeds. This characteristic translates to reduced switching losses, enabling more efficient and responsive power control in electronic systems.

A power semiconductor device may be fabricated on a semiconductor die (often more simply referred to as a “die”). The high-speed switching of SiC transistors presents a challenge when paralleling two or more die in a package (module); more specifically, these die may suffer from uneven current sharing among die and unwanted oscillations between die. The severity of the challenge increases with lower package inductance (parasitic), high current levels and quantity of die paralleled.

### BRIEF SUMMARY

It has been shown that by resistively decoupling the gate of a power semiconductor device, such as a power MOSFET, more gate charge may be held by the power semiconductor device to slow down turn-off of the power semiconductor device. In various applications, however, a power semiconductor device may be formed of a package (module) including a single die without an additional gate resistance, or an integrated gate resistor having a resistance value that may depend on factors such as a number of die in a package, package parasitic inductance, and/or application, without limitation. A manufacturer of power semiconductor devices may therefore have different versions of the same die that differ only in that one has no integrated gate resistor, and the others have an integrated gate resistor with different resistance values, which may be used in various packages. As power semiconductor device packaging evolves, parasitic inductance will likely decrease, and currents will increase. The need for multiple values of gate resistance will also likely increase and the ability to quickly address these needs may be beneficial in the marketplace.

Example implementations of the present disclosure are directed to semiconductor devices and, in particular, to a power semiconductor device with selectable gate resistance. Various features, aspects, and advantages of the present disclosure will be apparent from a reading of the following detailed description together with the accompanying figures, which are briefly described below.

The present disclosure includes any combination of two, three, four or more features or elements set forth in this disclosure, regardless of whether such features or elements are expressly combined or otherwise recited in a specific example implementation described herein. This disclosure is intended to be read holistically such that any separable features or elements of the disclosure, in any of its aspects and example implementations, should be viewed as combinable unless the context of the disclosure clearly dictates otherwise.

The present disclosure is provided merely for purposes of summarizing some example implementations so as to provide a basic understanding of some aspects of the disclosure. Accordingly, it will be appreciated that the described example implementations are merely examples and should not be construed to narrow the scope or spirit of the disclosure in any way. Other example implementations, aspects and advantages will become apparent from the following detailed description taken in conjunction with the accompanying figures which illustrate, by way of example, the principles of some described example implementations.

### BRIEF DESCRIPTION OF THE FIGURE(S)

Having thus described example implementations of the disclosure in general terms, reference will now be made to the accompanying figures, which are not necessarily drawn to scale, and wherein:

FIG. 1 illustrates a silicon carbide (SiC) metal-oxide-semiconductor field-effect transistor (MOSFET) wafer including a plurality of SiC MOSFET dies;

FIGS. 2A and 2B illustrate a SiC MOSFET including its die (FIG. 2A) with single-layer metallization, and its corresponding circuit representation (FIG. 2B);

FIGS. 3A and 3B illustrate a SiC MOSFET including its die (FIG. 3A) with single-layer metallization, and with an integrated gate resistor, and its corresponding circuit representation (FIG. 3B);

FIGS. 4A and 4B illustrate a SiC MOSFET including its die (FIG. 4A) with two-layer metallization, and with an integrated gate resistor, and its corresponding circuit representation (FIG. 4B);

FIG. 5 illustrates a power semiconductor device, according to some example implementations of the present disclosure;

FIG. 6 illustrates the power semiconductor device of FIG. 5 further including a semiconductor die, and package including leads, according to some example implementations;

FIG. 7 illustrates a power module that includes a package and a plurality of power semiconductor devices connected to form a circuit that is contained in the package, according to some example implementations;

FIGS. 8A and 8B illustrate a SiC MOSFET including its die (FIG. 5A) with two-layer metallization, and with a plurality of integrated, selectable gate resistors in a bus topology, and its corresponding circuit representation (FIG. 5B), according to some example implementations of the present disclosure;

FIGS. 9A and 9B illustrate a SiC MOSFET including its die (FIG. 6A) with two-layer metallization, and with a plurality of integrated, selectable gate resistors in a daisy-chain topology, and its corresponding circuit representation (FIG. 6B), according to some example implementations;

FIG. 10 illustrates manufacture of power semiconductor devices with different numbers of die, according to some example implementations; and

FIG. 11 is a flowchart illustrating various steps in a method 1100 according to various example implementations.

### DETAILED DESCRIPTION

Some implementations of the present disclosure will now be described more fully hereinafter with reference to the accompanying figures, in which some, but not all implementations of the disclosure are shown. Indeed, various implementations of the disclosure may be embodied in many different forms and should not be construed as limited to the implementations set forth herein; rather, these example implementations are provided so that this disclosure will be thorough and complete, and will fully convey the scope of the disclosure to those skilled in the art. Like reference numerals refer to like elements throughout.

Unless specified otherwise or clear from context, references to first, second or the like should not be construed to imply a particular order. A feature described as being above another feature (unless specified otherwise or clear from context) may instead be below, and vice versa; and similarly, features described as being to the left of another feature else may instead be to the right, and vice versa. Also, while reference may be made herein to quantitative measures, values, geometric relationships or the like, unless otherwise stated, any one or more if not all of these may be absolute or approximate to account for acceptable variations that may occur, such as those due to engineering tolerances or the like.

As used herein, unless specified otherwise or clear from context, the “or” of a set of operands is the “inclusive or” and thereby true if and only if one or more of the operands is true, as opposed to the “exclusive or” which is false when all of the operands are true. Thus, for example, “[A] or [B]” is true if [A] is true, or if [B] is true, or if both [A] and [B] are true. Further, the articles “a” and “an” mean “one or more,” unless specified otherwise or clear from context to be directed to a singular form.

Example implementations of the present disclosure relate generally to semiconductor devices and, in particular, to a power semiconductor device with selectable gate resistance. Example implementations may be described in the context of a transistor, such as a silicon carbide (SiC) metal-oxide-semiconductor field-effect transistor (MOSFET). It should be understood, however, that example implementations may be equally applicable to other power semiconductor devices. Likewise, example implementations may be equally applicable to transistors other than MOSFETs, as well as other MOSFETs other than SiC MOSFETs.

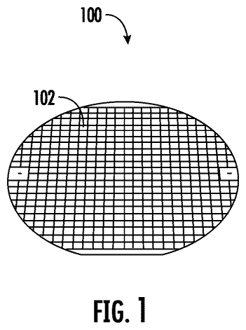

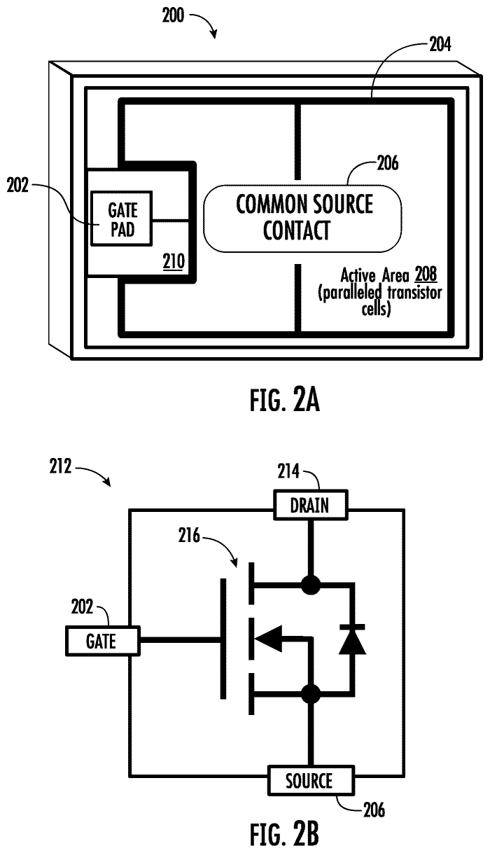

In electronics, a power semiconductor device (e.g., a SiC MOSFET) may be fabricated on a die, which may be produced in large batches on a die of semiconductor material. FIG. 1 illustrates a SiC MOSFET wafer 100 including a plurality of SiC MOSFET dies 102. FIG. 2A is an isometric projection of a SiC MOSFET die 200, which in some examples may correspond to SiC MOSFET die 102. As shown, the SiC MOSFET die 200 includes a common gate contact pad 202, a gate bus 204, a common source contact 206, an active area 208 of paralleled transistor cells (not separately shown), and a common drain contact (on back). The active area may include a single-layer metallization; and accordingly, the common gate contact pad may be formed on a non-active area 210 beyond the active area.

FIG. 2B illustrates a corresponding circuit representation 212 of the SiC MOSFET die 200, including the drain 214, and a representation 216 of the paralleled transistor cells.

As explained above, some power semiconductor devices, such as SiC MOSFETs, are capable of high-speed switching, which enables more efficient and responsive power control in electronic systems. The high-speed switching of these power semiconductor devices, however, presents a challenge when paralleling two or more die in a package (module).

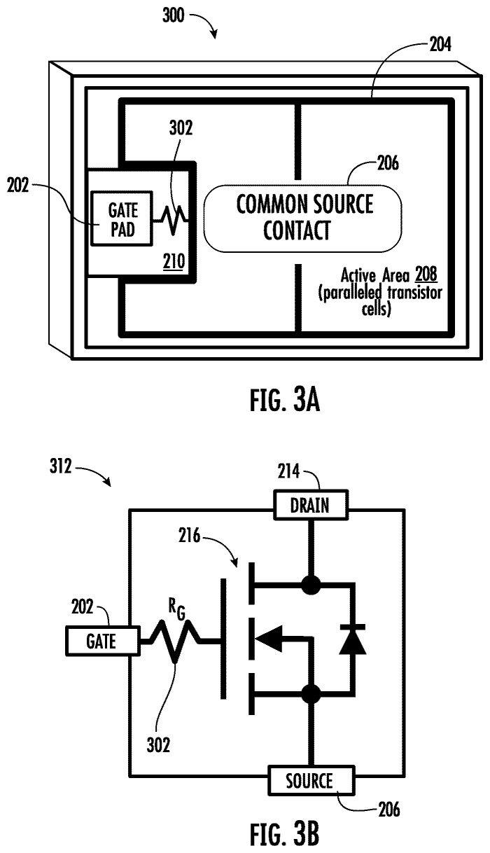

It has been shown that by resistively decoupling the gate of a power semiconductor device, such as a SiC MOSFET, more gate charge may be held by the power semiconductor device to slow down turn-off of the power semiconductor device. The power semiconductor device may be better protected from short circuit situations due to dissipation of energy during turn off over a longer duration of time. FIG. 3A is an isometric projection of a SiC MOSFET die 300, similar to SiC MOSFET die 200, but also including an integrated gate resistor 302. FIG. 3B illustrates a corresponding circuit representation 312 of the SiC MOSFET die 300, including the integrated gate resistor, which may have a resistance value R_{G}. More information on various examples in which the gate of a power semiconductor device is resistively decoupled may be found in U.S. Patent Application Publication No. 2023/0223933, entitled: Paralleled Transistor Cells of Power Semiconductor Devices, published Jul. 13, 2023, the content of which is incorporated by reference in its entirety.

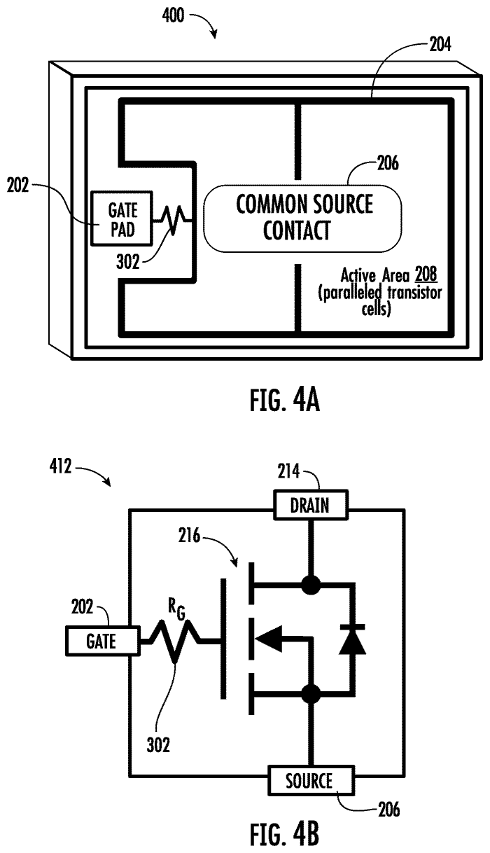

FIG. 4A is an isometric projection of a SiC MOSFET die 400 including a two-layer metallization. In a two-layer metal process, common gate contact pads may be placed over the active area of the die without increasing the die size. The SiC MOSFET die 400 in FIG. 4A is similar to SiC MOSFET die 300, including the integrated gate resistor 302 with resistance value R_{G}. The SiC MOSFET die 400 of FIG. 4A, however, includes two-layer metallization; and accordingly, the common gate contact pad 202 may be placed over the active area 208. FIG. 4B illustrates a corresponding circuit representation 412 of the SiC MOSFET die 400.

In various applications, a SiC MOSFET or other power semiconductor device may be formed of a package (module) including a single die without an integrated gate resistor. In other applications in which the package includes more than one die, one or more of the die may include an integrated gate resistor. A manufacturer of power semiconductor devices may therefore have different versions of the same die that differ only in that one has no integrated gate resistor, and the others have an integrated gate resistor with different resistance values, which may be used in various packages of different numbers of dies, for various applications.

In view of the foregoing, example implementations of the present disclosure provide a power semiconductor device including a die with a plurality of common gate contact pads, one or more of which are connected to an integrated gate resistor. In some examples, the power semiconductor device die may have no integrated gate resistor for one of the plurality of common gate contact pads, and include an integrated gate resistor for other of the plurality of common gate contact pads. In examples in which the power semiconductor device die includes multiple integrated gate resistors, the multiple integrated resistors may have respective resistance values. In some examples, one or more of the respective resistance values may be the same. Additionally or alternatively, in some examples, one or more one or more of the respective resistance values may be different. A resistance value (or no resistance value) may therefore be selectable in a circuit including the power semiconductor device by connecting to a respective one of the plurality of common gate contact pads.

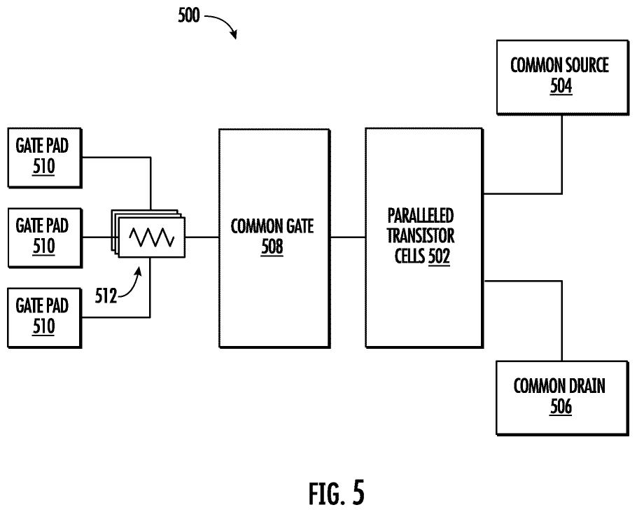

FIG. 5 illustrates a power semiconductor device 500, according to some example implementations of the present disclosure. As shown, the power semiconductor device includes paralleled transistor cells 502. The power semiconductor device also includes a common source 504, a common drain 506 and a common gate 508 operatively coupled to the paralleled transistor cells. The power semiconductor device includes a plurality of common gate contact pads 510 operatively coupled to the common gate, and one or more resistors 512 coupled to respective one or more common gate contact pads of the plurality of common gate contact pads. The one or more resistors are coupled between the respective one or more common gate contact pads and the common gate. In this regard, the plurality of common gate contact pads provide a selectable resistive decoupling of the common gate by connection of one of the plurality of common gate contact pads.

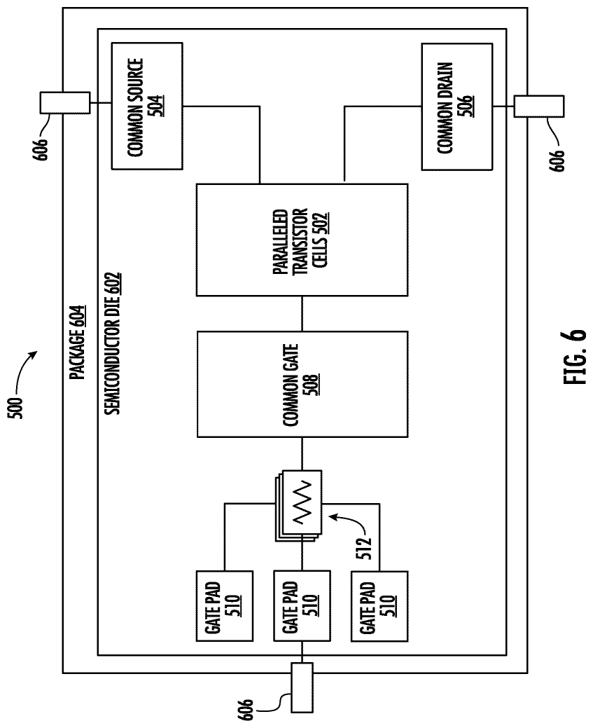

As shown in FIG. 6, in some examples, the power semiconductor device 500 is fabricated on a semiconductor die 602. In some of these examples, the power semiconductor device further includes a package 604 that contains the semiconductor die. As shown, the package includes leads 606 operatively coupled to the common source 504, the common drain 506, and one of the plurality of common gate contact pads 510 that are operatively coupled to the common gate 508 via the one or more resistors 512.

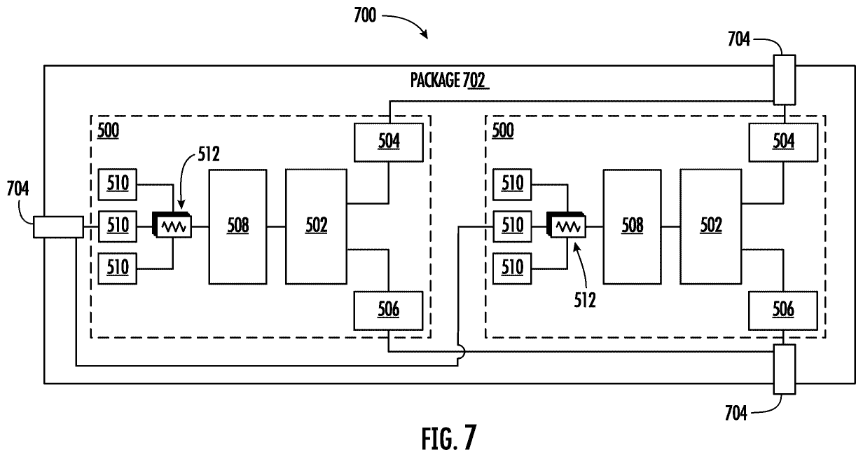

FIG. 7 illustrates a power module 700 that includes a package 702 and a plurality of power semiconductor devices 500 connected to form a circuit that is contained in the package. As shown, the package includes a lead 704 operatively coupled to one of the plurality of common gate pads 510 of respective ones of the plurality of power semiconductor devices. In some examples, the package also includes leads operatively coupled to the common sources 504 and common drains 506 of the plurality of power semiconductor devices.

The power semiconductor device of example implementations may therefore provide a single die solution that replaces multiple versions of a die with no integrated gate resistor or integrated gate resistors with different resistance values. The power semiconductor device die of example implementations may be logistically simpler to manufacture in that one die may meet all packaging needs. Only one mask set may be required, instead of multiple mask sets for multiple versions of the die. Likewise, changing gate resistance values in a module, or new module, may be manufactured without a new die version. This may be useful for existing modules to meet new application needs, or in new modules where the trend is to minimize parasitic inductance.

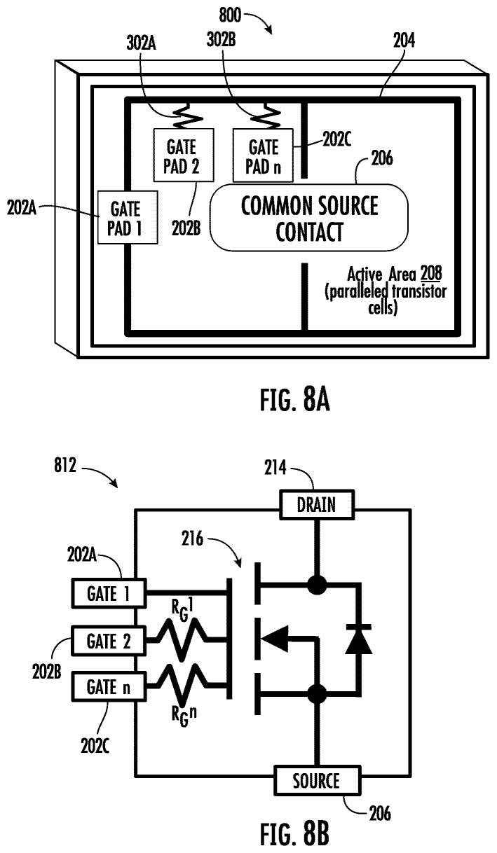

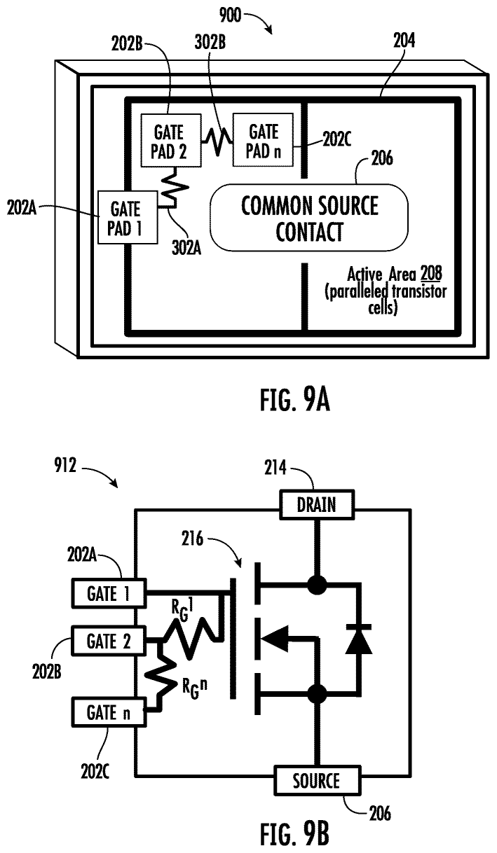

To further illustrate the power semiconductor device and power module of some example implementations in the context of a SiC MOSFET, reference is now made to the isometric projections of FIGS. 8A and 9A, and corresponding circuit representations of FIGS. 8B and 9B.

FIG. 8A is an isometric projection of a SiC MOSFET die 800, similar to SiC MOSFET die 400, including two-layer metallization. The SiC MOSFET die 800 also includes a plurality of common gate contact pads 202A, 202B, 202C. The SiC MOSFET die 800 may have no integrated gate resistor for a first of the common gate contact pads 202A. The other of the common gate contact pads 202B, 202C may be connected to respective integrated gate resistors 302A, 302B, which resistively decouple the other of the common gate contact pads. FIG. 8B illustrates a corresponding circuit representation 812 of the SiC MOSFET die 800, including the integrated gate resistors 302A, 302B, which may have respective resistance values R_{G}1, R_{G}n.

The plurality of common gate contact pads 202A, 202B, 202C on the SiC MOSFET die 800 are each connected to the gate bus 204 (directly or via a respective one of the integrated gate resistors 302A, 302B) in a bus topology. In this arrangement, the first of the common gate contact pads 202A may be connected to select no additional gate resistance. A second of the common gate contact pads 202B may be connected to select an additional gate resistance of a first resistance value R_{G}1; and a third of the common gate contact pads 202C may be connected to select an additional gate resistance of a second resistance value R_{G}n.

FIG. 9A is an isometric projection of a SiC MOSFET die 900, similar to SiC MOSFET die 800, but in which a second and third of the common gate contact pads 202B and 202C are daisy-chained to the first of the common gate contact pads 202A via respective ones of the integrated gate resistors 302A, 302B. FIG. 9B illustrates a corresponding circuit representation 912 of the SiC MOSFET die 900. In this arrangement, the first of the common gate contact pads 202A may be connected to select no additional gate resistance. The second of the common gate contact pads 202B may be connected to select an additional gate resistance of a first resistance value R_{G}1; and the third of the common gate contact pads 202C may be connected to select an additional gate resistance of a second resistance value (R_{G}1+R_{G}n).

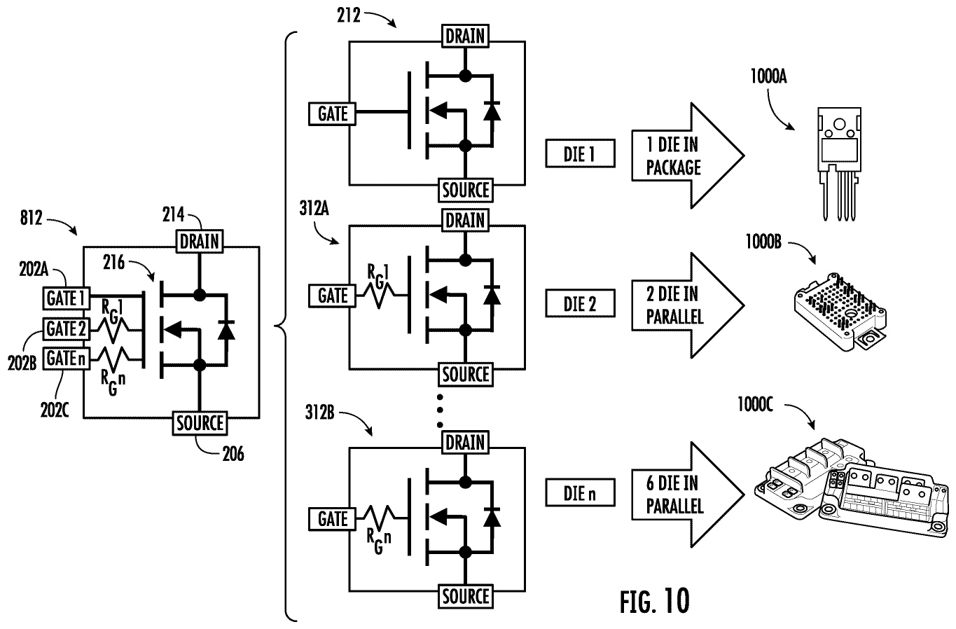

FIG. 10 illustrates manufacture of power semiconductor devices 1000A, 1000B, 1000C with different numbers of die, according to some example implementations. As shown, a power semiconductor device 1000A may be manufactured to include one SiC MOSFET die 200 without an integrated gate resistor (shown by its corresponding circuit representation 212) encapsulated in a package.

The other power semiconductor devices 1000B, 1000C may be manufactured to include a plurality of SiC MOSFET dies 312, with an integrated gate resistor, connected in parallel, and encapsulated in a package. These power semiconductor devices include different numbers of SiC MOSFET dies, and therefore include integrated gate resistors with different resistance values. These power semiconductor devices may therefore be manufactured with different versions of SiC MOSFET die 312. As shown, for example, power semiconductor device 1000B may be manufactured to include two parallel SiC MOSFET die 312A with an integrated gate resistor having resistance value R_{G}1 (shown by its corresponding circuit representation 312A). Power semiconductor device 1000C may be manufactured to include six parallel SiC MOSFET die 312B with an integrated gate resistor having resistance value R_{G}n (shown by its corresponding circuit representation 312B).

According to example implementations of the present disclosure, the individual versions of the SiC MOSFET dies in power semiconductor devices 1000A, 1000B, 1000C may be replaced with one SiC MOSFET die 800 (or SiC MOSFET die 900) including selectable integrated gate resistance values. In power semiconductor device 700A, the first of the common gate contact pads 202A may be connected to a lead of the package to select no additional gate resistance. In power semiconductor device 1000B, the second of the common gate contact pads 202B of two parallel SiC MOSFET dies 800 may be connected to a lead of the package to select an additional gate resistance value R_{G}1. In power semiconductor device 1000C, the third of the common gate contact pads 202C of six parallel SiC MOSFET dies 800 may be connected to a lead of the package to select an additional gate resistance value R_{G}n.

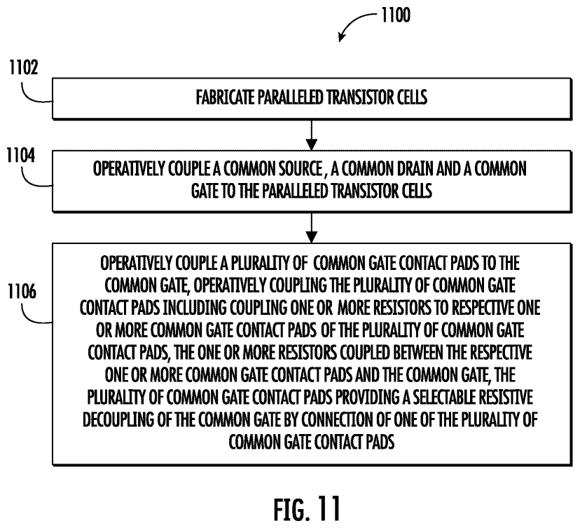

FIG. 11 is a flowchart illustrating various steps in a method 1100 according to various example implementations. The method includes fabricating paralleled transistor cells, as shown at block 11802. The method includes operatively coupling a common source, a common drain and a common gate to the paralleled transistor cells, as shown at block 1104. And the method includes operatively coupling a plurality of common gate contact pads to the common gate, operatively coupling the plurality of common gate contact pads including coupling one or more resistors to respective one or more common gate contact pads of the plurality of common gate contact pads, as shown at block 1106. The one or more resistors are coupled between the respective one or more common gate contact pads and the common gate, and the plurality of common gate contact pads provide a selectable resistive decoupling of the common gate by connection of one of the plurality of common gate contact pads.

As explained above and reiterated below, the present disclosure includes, without limitation, the following example implementations.

Clause 1. A power semiconductor device comprising: paralleled transistor cells; a common source, a common drain and a common gate operatively coupled to the paralleled transistor cells; a plurality of common gate contact pads operatively coupled to the common gate; and one or more resistors coupled to respective one or more common gate contact pads of the plurality of common gate contact pads, the one or more resistors coupled between the respective one or more common gate contact pads and the common gate, the plurality of common gate contact pads providing a selectable resistive decoupling of the common gate by connection of one of the plurality of common gate contact pads.

Clause 2. The power semiconductor device of clause 1, wherein the power semiconductor device is fabricated on a semiconductor die.

Clause 3. The power semiconductor device of clause 2, wherein the power semiconductor device further comprises a package that contains the semiconductor die, the package comprising leads operatively coupled to the common source, the common drain, and the one of the plurality of common gate contact pads.

Clause 4. The power semiconductor device of any of clauses 1 to 3, wherein the power semiconductor device has a two metal layer structure in which the plurality of common gate contact pads are disposed over the paralleled transistor cells.

Clause 5. The power semiconductor device of any of clauses 1 to 4, wherein the plurality of common gate contact pads comprise a common gate contact pad coupled to the common gate independent of the one or more resistors, and the respective one or more common gate contact pads that are coupled to the one or more resistors.

Clause 6. The power semiconductor device of any of clauses 1 to 5, wherein the respective one or more common gate contact pads comprise a first common gate contact pad and a second common gate contact pad, and wherein the one or more resistors comprise a first resistor coupled to the first common gate contact pad, and a second resistor coupled to the second common gate contact pad.

Clause 7. The power semiconductor device of clause 6, wherein the first resistor and the second resistor have respective resistance values.

Clause 8. The power semiconductor device of clause 6 or clause 7, wherein the first resistor is coupled to the first common gate contact pad and the common gate, and the second resistor is coupled to the second common gate contact pad and the common gate.

Clause 9. The power semiconductor device of any of clauses 6 to 8, wherein the first resistor is coupled to the first common gate contact pad and the common gate, and the second resistor is coupled to the second common gate contact pad, and between the first common gate contact pad and the first resistor.

Clause 10. The power semiconductor device of clause 9, wherein the first resistor and the second resistor have respective resistance values.

Clause 11. The power semiconductor device of any of clauses 1 to 10, wherein the plurality of common gate contact pads comprise a common gate contact pad coupled to the common gate independent of the one or more resistors, and the respective one or more common gate contact pads that comprise a first common gate contact pad and a second common gate contact pad, and wherein the one or more resistors comprise a first resistor coupled to the first common gate contact pad, and a second resistor coupled to the second common gate contact pad.

Clause 12. The power semiconductor device of any of clauses 1 to 11, wherein the paralleled transistor cells comprise metal-oxide-semiconductor field-effect transistor cells.

Clause 13. The power semiconductor device of any of clauses 1 to 12, wherein the paralleled transistor cells comprise silicon-carbide (SiC) transistor cells.

Clause 14. The power semiconductor device of clause 13, wherein the SiC transistor cells comprise metal-oxide-semiconductor field-effect transistor cells.

Clause 15. A power module comprising: a package; and a plurality of power semiconductor devices connected to form a circuit that is contained in the package, respective ones of the plurality of power semiconductor devices comprising: paralleled transistor cells; a common source, a common drain and a common gate operatively coupled to the paralleled transistor cells; a plurality of common gate contact pads operatively coupled to the common gate; and one or more resistors coupled to respective one or more common gate contact pads of the plurality of common gate contact pads, the one or more resistors coupled between the respective one or more common gate contact pads and the common gate, the plurality of common gate contact pads providing a selectable resistive decoupling of the common gate by connection of one of the plurality of common gate contact pads, wherein the package comprises a lead operatively coupled to the one of the plurality of common gate pads of the respective ones of the plurality of power semiconductor devices.

Clause 16. The power module of clause 15, wherein the power semiconductor devices are fabricated on respective semiconductor dies.

Clause 17. The power module of clause 15 or clause 16, wherein the respective ones of the power semiconductor devices have a two metal layer structure in which the plurality of common gate contact pads are disposed over the paralleled transistor cells.

Clause 18. The power module of any of clauses 15 to 17, wherein the plurality of common gate contact pads comprise a common gate contact pad coupled to the common gate independent of the one or more resistors, and the respective one or more common gate contact pads that are coupled to the one or more resistors.

Clause 19. The power module of any of clauses 15 to 18, wherein the respective one or more common gate contact pads comprise a first common gate contact pad and a second common gate contact pad, and wherein the one or more resistors comprise a first resistor coupled to the first common gate contact pad, and a second resistor coupled to the second common gate contact pad.

Clause 20. A method comprising: fabricating paralleled transistor cells; operatively coupling a common source, a common drain and a common gate to the paralleled transistor cells; and operatively coupling a plurality of common gate contact pads to the common gate, operatively coupling the plurality of common gate contact pads including coupling one or more resistors to respective one or more common gate contact pads of the plurality of common gate contact pads, the one or more resistors coupled between the respective one or more common gate contact pads and the common gate, the plurality of common gate contact pads providing a selectable resistive decoupling of the common gate by connection of one of the plurality of common gate contact pads.

Many modifications and other implementations of the disclosure set forth herein will come to mind to one skilled in the art to which the disclosure pertains having the benefit of the teachings presented in the foregoing description and the associated figures. Therefore, it is to be understood that the disclosure is not to be limited to the specific implementations disclosed and that modifications and other implementations are intended to be included within the scope of the appended claims. Moreover, although the foregoing description and the associated figures describe example implementations in the context of certain example combinations of elements and/or functions, it should be appreciated that different combinations of elements and/or functions may be provided by alternative implementations without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A power semiconductor device comprising:
paralleled transistor cells;
a common source, a common drain and a common gate operatively coupled to the paralleled transistor cells;
a plurality of common gate contact pads operatively coupled to the common gate; and
one or more resistors coupled to respective one or more common gate contact pads of the plurality of common gate contact pads, the one or more resistors coupled between the respective one or more common gate contact pads and the common gate, the plurality of common gate contact pads providing a selectable resistive decoupling of the common gate by connection of one of the plurality of common gate contact pads.

2. The power semiconductor device of claim 1, wherein the power semiconductor device is fabricated on a semiconductor die.

3. The power semiconductor device of claim 2, wherein the power semiconductor device further comprises a package that contains the semiconductor die, the package comprising leads operatively coupled to the common source, the common drain, and the one of the plurality of common gate contact pads.

4. The power semiconductor device of claim 1, wherein the power semiconductor device has a two metal layer structure in which the plurality of common gate contact pads are disposed over the paralleled transistor cells.

5. The power semiconductor device of claim 1, wherein the plurality of common gate contact pads comprise a common gate contact pad coupled to the common gate independent of the one or more resistors, and the respective one or more common gate contact pads that are coupled to the one or more resistors.

6. The power semiconductor device of claim 1, wherein the respective one or more common gate contact pads comprise a first common gate contact pad and a second common gate contact pad, and
wherein the one or more resistors comprise a first resistor coupled to the first common gate contact pad, and a second resistor coupled to the second common gate contact pad.

7. The power semiconductor device of claim 6, wherein the first resistor and the second resistor have respective resistance values.

8. The power semiconductor device of claim 6, wherein the first resistor is coupled to the first common gate contact pad and the common gate, and the second resistor is coupled to the second common gate contact pad and the common gate.

9. The power semiconductor device of claim 6, wherein the first resistor is coupled to the first common gate contact pad and the common gate, and the second resistor is coupled to the second common gate contact pad, and between the first common gate contact pad and the first resistor.

10. The power semiconductor device of claim 9, wherein the first resistor and the second resistor have respective resistance values.

11. The power semiconductor device of claim 1, wherein the plurality of common gate contact pads comprise a common gate contact pad coupled to the common gate independent of the one or more resistors, and the respective one or more common gate contact pads that comprise a first common gate contact pad and a second common gate contact pad, and
wherein the one or more resistors comprise a first resistor coupled to the first common gate contact pad, and a second resistor coupled to the second common gate contact pad.

12. The power semiconductor device of claim 1, wherein the paralleled transistor cells comprise metal-oxide-semiconductor field-effect transistor cells.

13. The power semiconductor device of claim 1, wherein the paralleled transistor cells comprise silicon-carbide (SiC) transistor cells.

14. The power semiconductor device of claim 13, wherein the SiC transistor cells comprise metal-oxide-semiconductor field-effect transistor cells.

15. A power module comprising:
a package; and
a plurality of power semiconductor devices connected to form a circuit that is contained in the package, respective ones of the plurality of power semiconductor devices comprising:
paralleled transistor cells;
a common source, a common drain and a common gate operatively coupled to the paralleled transistor cells;
a plurality of common gate contact pads operatively coupled to the common gate; and
one or more resistors coupled to respective one or more common gate contact pads of the plurality of common gate contact pads, the one or more resistors coupled between the respective one or more common gate contact pads and the common gate, the plurality of common gate contact pads providing a selectable resistive decoupling of the common gate by connection of one of the plurality of common gate contact pads,
wherein the package comprises a lead operatively coupled to the one of the plurality of common gate pads of the respective ones of the plurality of power semiconductor devices.

16. The power module of claim 15, wherein the power semiconductor devices are fabricated on respective semiconductor dies.

17. The power module of claim 15, wherein the respective ones of the power semiconductor devices have a two metal layer structure in which the plurality of common gate contact pads are disposed over the paralleled transistor cells.

18. The power module of claim 15, wherein the plurality of common gate contact pads comprise a common gate contact pad coupled to the common gate independent of the one or more resistors, and the respective one or more common gate contact pads that are coupled to the one or more resistors.

19. The power module of claim 15, wherein the respective one or more common gate contact pads comprise a first common gate contact pad and a second common gate contact pad, and
wherein the one or more resistors comprise a first resistor coupled to the first common gate contact pad, and a second resistor coupled to the second common gate contact pad.

20. A method comprising:
fabricating paralleled transistor cells;
operatively coupling a common source, a common drain and a common gate to the paralleled transistor cells; and
operatively coupling a plurality of common gate contact pads to the common gate, operatively coupling the plurality of common gate contact pads including coupling one or more resistors to respective one or more common gate contact pads of the plurality of common gate contact pads, the one or more resistors coupled between the respective one or more common gate contact pads and the common gate, the plurality of common gate contact pads providing a selectable resistive decoupling of the common gate by connection of one of the plurality of common gate contact pads.
